(19) United States
(12) Patent Application Publication
(10) Pub. No.: US 2010/0225001 A1
(43) Pub. Date: Sep. 9, 2010

(54) MANUFACTURING METHOD OF SEMICONDUCTOR DEVICE, SEMICONDUCTOR DEVICE, AND ELECTRONIC DEVICE

(75) Inventor: Toru HIZUME, Nagano-shi (JP)

Correspondence Address: DRINKER BIDDLE & REATH (DC), 1500 K STREET, N.W., SUITE 1100, WASHINGTON, DC, 20005-1209, US

(73) Assignee: Shinko Electric Industries Co., Ltd., Nagano-shi (JP)

(21) Appl. No.: 12/709,911

(22) Filed: Feb. 22, 2010

(30) Foreign Application Priority Data
Mar. 3, 2009 (JP) P.2009-048955

(51) Int. Cl. H01L 23/48; H01L 21/56

(52) U.S. Cl. 257/773; 438/118; 257/E21.502; 257/E23.011

(57) ABSTRACT

In a method for manufacturing a semiconductor device having a plate-shaped member, a semiconductor element, and a wiring board, the manufacturing method for the semiconductor device includes: a concave portion forming step (S101) of the plate-shaped member; a semiconductor element provisionally adhering step (S102) for provisionally adhering the semiconductor element to a portion located in the vicinity of a first corner portion of a concave portion; a semiconductor element aligning step (S103) for aligning the semiconductor element based upon thermal expansion of a semiconductor element depressing member; a resin molding step (S104) of the plate-shaped member; an electrode pad exposing step (S105) for exposing an electrode pad by grinding the plate-shaped member; and a wiring board stacking step (S106) for stacking layers by directly connecting the exposed electrode pad to the wiring layer on the ground plane of the plate-shaped member.

### CROSS-REFERENCE TO RELATED APPLICATION

This application is based on and claims priority under 35 U.S.C. §119 from Japanese Patent Application No. 2009-048955 filed on Mar. 3, 2009.

### BACKGROUND OF THE INVENTION

1. Technical Field

The present invention is related to a method of manufacturing a semiconductor device equipped with semiconductor element and a wiring board which is electrically connected to the semiconductor element, and related to a semiconductor device and an electronic device.

2. Related Art

FIG. 1 is a sectional view of a conventional semiconductor device.

In FIG. 1, the conventional semiconductor device 200 has a wiring board 201, a semiconductor element 202, a plurality of semiconductor element-purpose bumps 203, and a molded resin 204.

The wiring board 201 has a plurality of insulating layers 205, and a plurality of wiring layers 206 provided in the plurality of insulating layers 205. The semiconductor element 202 is arranged on one plane of the wiring board 201, and is electrically connected, for example, via the solder bumps 203 to the wiring layers 206 of portions exposed from the plurality of insulating layers 205 (refer to, for instance, patent publication 1).

Such direct joining of a semiconductor element to a wiring board is normally referred to as flip chip bonding, or C4 (Controlled Collapse Chip Connection), and while solder bumps are employed, a self-alignment of the semiconductor element is carried out by way of surface tension of melted solder.

### [Patent Publication 1] JP-A-2006-294692

However, since the semiconductor element 202 is electrically connected to the wiring board 201 via the bumps 203 in the conventional semiconductor device 200, the bumps 203 are required to be arranged in such a manner that the adjoining bumps 203 do not contact to each other. As a result, there is such a problem that an arranging pitch of the bumps 203 can be hardly reduced, and the wiring layers 206 of the portions which are connected to the bumps 203 cannot be arranged on the same plane in a very fine mode. Also, in the case that the solder bumps are employed as the bumps 203, there is a risk that a shortcircuit may occur due to migrations of the solder. Thus, there is another problem that electric connection reliability between the wiring board 201 and the semiconductor element 202 is lowered.

### SUMMARY OF THE INVENTION

The present invention has been made to solve the above-described problems, and therefore, has an object to provide a manufacturing method for a semiconductor device, a semiconductor device, and an electronic device, which are capable of making wiring density of wiring layers in a very fine mode, which are provided in a wiring board, and are capable of improving electric connection reliability between a semiconductor element and the wiring board by performing the below-mentioned manufacturing method: That is, since the semiconductor element is caused to abut against wall planes of a penetration portion of a plate-shaped member, or the like, which stores thereinto the semiconductor element, an alignment of the semiconductor element is carried out in high precision by utilizing the solid wall planes, and thus, the high positional setting (alignment) precision is secured.

According to a first aspect of the invention, there is provided a method for manufacturing a semiconductor device having a plate-shaped member which stores thereinto a semiconductor element,

the manufacturing method including:

a concave portion forming step for forming a concave portion in the plate-shaped member, an opening portion of the concave portion being a rectangle and the concave portion being used to store thereinto the semiconductor element;

a semiconductor element provisionally adhering step for provisionally adhering the semiconductor element to an adhesive layer in such a manner that the adhesive layer is formed on a bottom of the concave portion, the semiconductor element is mounted on a portion of the concave portion in the vicinity of a first corner portion thereof, and at least a portion of an electrode pad of the semiconductor element is embedded in the adhesive layer; and

a semiconductor element aligning step for aligning the semiconductor element in such a manner that a semiconductor element depressing member for aligning the semiconductor element is formed at a second corner portion located opposite to the first corner portion of the concave portion, and the semiconductor element depressing member causes the semiconductor element to abut against two wall planes which constitute the first corner portion based upon expansion of the semiconductor element depressing member due to heating operation.

According to a second aspect of the invention, there is provided the manufacturing method of a semiconductor element as in the first aspect, wherein

a thermal expansion coefficient of the semiconductor element depressing member is higher than or equal to 300×10⁻⁶/° C.

According to a third aspect of the invention, there is provided the manufacturing method of a semiconductor element as in the first or second aspect, wherein

the concave portion forming step includes a penetration electrode forming step for forming a penetration electrode at a circumferential area of the opening portion of the concave portion in the plate-shaped member.

According to a fourth aspect of the invention, there is provided the manufacturing method of a semiconductor element as in any one of the first to third aspects, further including:

a resin sealing step for sealing the concave portion by a resin, in which the semiconductor element and the semiconductor element depressing member are stored;

an electrode pad exposing step for exposing the electrode pad from the plate-shaped member; and

a wiring board stacking step for stacking a wiring board having an insulating layer and a wiring layer electrically connected to the electrode pad on the plate-shaped member in the form of a single layer or multiple layers.

According to a fifth aspect of the invention, there is provided the manufacturing method of a semiconductor element as in any one of the first to third aspects, further including:

a sealing resin removing step for forming a resin layer made by a sealing resin on a plane of the semiconductor element on the side opposite to the side of the electrode pad, and a plane of the plate-shaped member on the same side as the opposite side of the semiconductor element, and for removing a portion of the resin layer;

an electrode pad exposing step for exposing the electrode pad from the plate-shaped member; and

a wiring board stacking step for stacking a wiring board having an insulating layer and a wiring layer electrically connected to the electrode pad on the plate-shaped member in the form of a single layer or multiple layers.

According to a sixth aspect of the invention, there is provided a semiconductor device including:

a plate-shaped member for storing thereinto a semiconductor element, wherein

the plate-shaped member has a penetration portion having a rectangular opening shape, in which the semiconductor element and a semiconductor element depressing member for aligning the semiconductor element are provided;

the semiconductor element depressing member is provided at a second corner portion of the penetration portion, which is located opposite to a first corner portion thereof;

the semiconductor element is aligned in such a manner that the semiconductor element abuts against two wall portions which constitute the first corner portion based upon thermal expansion of the semiconductor element depressing member; and

the semiconductor element and the semiconductor element depressing member provided in the penetration portion are sealed by a sealing resin.

According to a seventh aspect of the invention, there is provided the semiconductor device as in the sixth aspect, wherein

a thermal expansion coefficient of the semiconductor element depressing member is higher than or equal to 300×10⁻⁶/° C.

According to an eighth aspect of the invention, there is provided the semiconductor device as in the sixth or seventh aspect, wherein

a wiring board having a wiring layer which is connected to an electrode pad provided in the semiconductor element is stacked in a single layer form or a multilayer form.

According to a ninth aspect of the invention, there is provided the semiconductor device as in any one of the sixth to eighth aspects, wherein

a penetration electrode is provided at a circumferential area of the penetration portion.

According to a tenth aspect of the invention, there is provided the semiconductor device as in any one of the sixth to ninth aspects, wherein

a corner portion at the first corner portion of the penetration portion has a notch shape.

According to an eleventh aspect of the invention, there is provided an electronic device including:

the semiconductor device as in any one of the sixth to tenth aspects;

another semiconductor device; and

an internal connection terminal which is arranged between the semiconductor device and the another semiconductor device and electrically connects the semiconductor device to the another semiconductor device.

In accordance with the present invention, the wiring density of the wiring layers provided in the wiring board can be made in the very fine mode, and the electric connection reliability between the semiconductor element and the wiring board can be improved.

### BRIEF DESCRIPTION OF THE DRAWINGS

FIG. 1 is a sectional view for showing the conventional semiconductor device;

FIG. 2 is a diagram for exemplifying steps of a manufacturing method for a semiconductor device, according to a first embodiment mode of the present invention;

FIG. 3 is a diagram (No. 1) for exemplifying the manufacturing method for the semiconductor device according to the first embodiment mode of the present invention;

FIG. 4 is a diagram (No. 2) for exemplifying the manufacturing method for the semiconductor device according to the first embodiment mode of the present invention;

FIG. 5 is a diagram (No. 3) for exemplifying the manufacturing method for the semiconductor device according to the first embodiment mode of the present invention;

FIG. 6 is a diagram (No. 4) for exemplifying the manufacturing method for the semiconductor device according to the first embodiment mode of the present invention;

FIG. 7 is a diagram (No. 5) for exemplifying the manufacturing method for the semiconductor device according to the first embodiment mode of the present invention;

FIG. 8 is a diagram (No. 6) for exemplifying the manufacturing method for the semiconductor device according to the first embodiment mode of the present invention;

FIG. 9 is a diagram (No. 7) for exemplifying the manufacturing method for the semiconductor device according to the first embodiment mode of the present invention;

FIG. 10 is a diagram (No. 8) for exemplifying the manufacturing method for the semiconductor device according to the first embodiment mode of the present invention;

FIG. 11 is a diagram (No. 9) for exemplifying the manufacturing method for the semiconductor device according to the first embodiment mode of the present invention;

FIG. 12 is a diagram for exemplifying a manufacturing method for a semiconductor device, according to a modification 1 of the first embodiment mode of the present invention;

FIG. 13 is a diagram (No. 1) for exemplifying a manufacturing method for a semiconductor device, according to a modification 2 of the first embodiment mode of the present invention;

FIG. 14 is a diagram (No. 2) for exemplifying the manufacturing method for the semiconductor device according to the modification 2 of the first embodiment mode of the present invention;

FIG. 15 is a diagram (No. 3) for exemplifying the manufacturing method for the semiconductor device according to the modification 2 of the first embodiment mode of the present invention;

FIG. 16 is a diagram for exemplifying a manufacturing method for a semiconductor device, according to a modification 3 of the first embodiment mode of the present invention;

FIG. 17 is a diagram for exemplifying a manufacturing method for a semiconductor device, according to a modification 4 of the first embodiment mode of the present invention;

FIG. 18 is a diagram (No. 1) for exemplifying the manufacturing method for the semiconductor device according to the modification 4 of the first embodiment mode of the present invention;

FIG. 19 is a diagram (No. 2) for exemplifying the manufacturing method for the semiconductor device according to the modification 4 of the first embodiment mode of the present invention;

FIG. 20 is a diagram (No. 3) for exemplifying the manufacturing method for the semiconductor device according to the modification 4 of the first embodiment mode of the present invention;

FIG. 21 is a diagram for exemplifying steps of a manufacturing method for a semiconductor device, according to a modification 5 of the first embodiment mode of the present invention;

FIG. 22 is a diagram for exemplifying the manufacturing method for the semiconductor device according to the modification 5 of the first embodiment mode of the present invention;

FIG. 23 is a diagram for exemplifying a semiconductor device according to a second embodiment mode of the present invention;

FIG. 24 is a plan view for exemplifying the semiconductor device according to the second embodiment mode of the present invention;

FIG. 25 is a diagram for exemplifying a semiconductor device according to a modification according to the second embodiment mode of the present invention;

FIG. 26 is a plan view for exemplifying the semiconductor device according to the modification of the second embodiment mode of the present invention; and

FIG. 27 is a diagram for exemplifying an electronic device according to a third embodiment mode of the present invention.

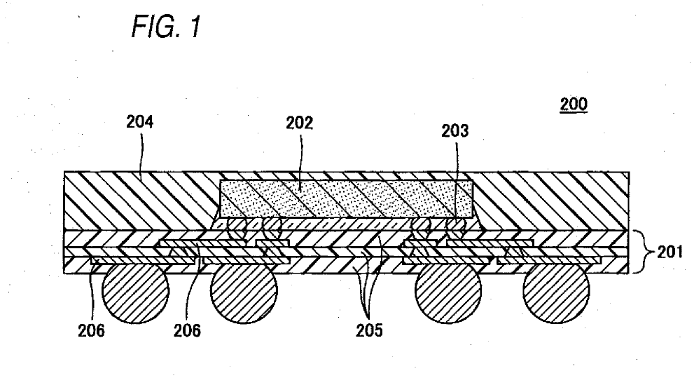

### DETAILED DESCRIPTION OF THE PREFERRED EMBODIMENTS

A description is made of embodiment modes of the present invention based upon drawings.

### First Embodiment Mode

A first embodiment mode of the present invention is an exemplification of a method for manufacturing a semiconductor device, by which a semiconductor element can be aligned in high precision.

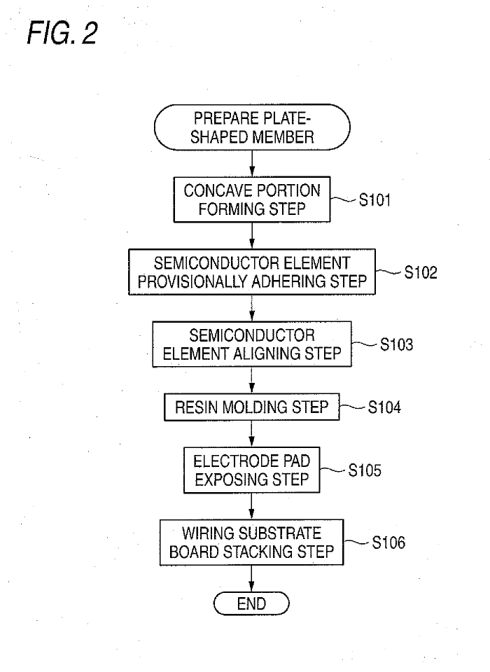

FIG. 2 is a flowchart for exemplifying steps of a method for manufacturing a semiconductor device, according to a first embodiment mode of the present invention. The manufacturing steps contain a concave portion forming step (S101), a semiconductor element provisionally adhering step (S102), a semiconductor element aligning step (S103), a resin molding step (S104), an electrode pad exposing step (S105), and a wiring board stacking step (S106).

Referring now to typical drawings of the respective steps, the steps of the method for manufacturing the semiconductor device will be sequentially described.

### (S101: Concave Portion Forming Step)

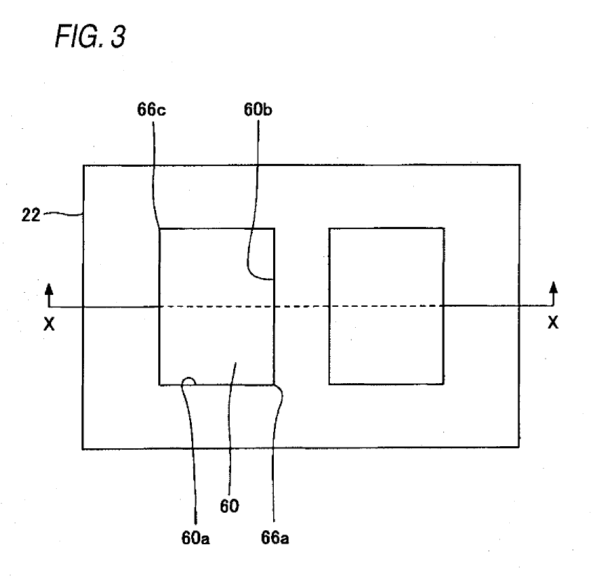

FIG. 3 is a plan view for indicating a forming condition of a space of a concave portion formed in a plate-shaped member.

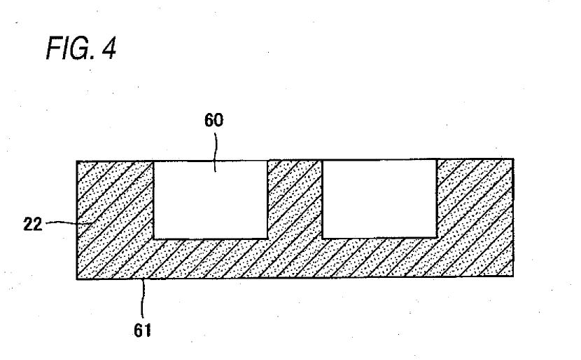

FIG. 4 is a sectional view for representing the plate-shaped member, taken along a cutting line “X-X” indicated in FIG. 3.

As a material of the plate-shaped member 22, either silicon or glass may be employed. A concave portion 60 is a space used to store thereinto a semiconductor element and a semiconductor element depressing member, which will be explained later.

As one example, a manufacturing method of a semiconductor device on which two semiconductor elements are mounted is represented, and two concave portions 60 are illustrated. In one concave portion 60 of FIG. 3, both a wall plane 60a and another wall plane 60b of the concave portion 60, which form a first corner portion 66a thereof, constitute a reference plane against which side planes of a semiconductor element will abut later so as to align the semiconductor element. Positioning of the concave portion 60, and forming of surfaces of the wall portion 60a and the wall portion 60b are carried out in high processing precision. When the concave portion 60 is processed, for instance, while a photolithography method is utilized, a resist mask is formed, and the formed resist mask is dry-etched. Also, a grinding machine, a polishing machine, and the like are utilized, if required. A depth of the concave portion 60 is, for example, 200 μm.

### (S102: Semiconductor Element Provisionally Adhering Step)

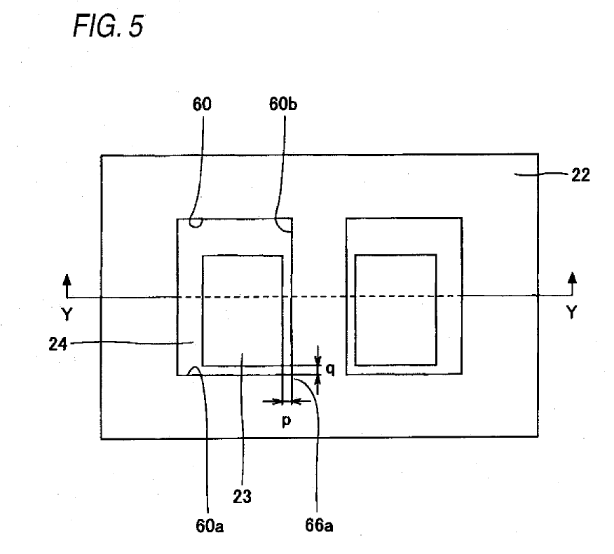

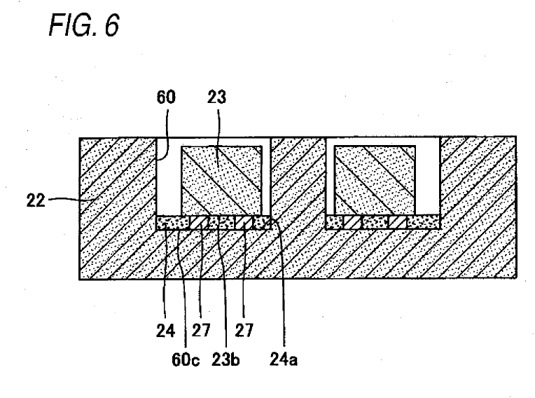

FIG. 5 shows a situation condition under which semiconductor elements are provisionally adhered to bottom portions near first corner portions of concave portions in the semiconductor element provisionally adhering step. FIG. 6 is a sectional view for indicating a plate-shaped member, taken along a cutting line “Y-Y” in FIG. 5.

A layer of an adhesive agent 24 is previously formed on a bottom portion 60c of one concave portion 60, and a semiconductor element 23 is provisionally adhered to the bottom portion 60c by a pickup apparatus or the like (not shown). At this time, the semiconductor element 23 on the side of a forming plane 23b of electrode pads 27 is provisionally adhered. The semiconductor element 23 is depressed, if required, in order that at least a portion of the electrode pads 27 of the semiconductor element 23 is embedded in the layer of the adhesive agent 24, and thus, is brought into such a condition that the portion thereof reaches the bottom portion 60c of the concave portion 60. Also, when the semiconductor element 23 is provisionally adhered, an interval “q” between the semiconductor element 23 and the wall plane 60a, and another interval “p” between the semiconductor element 23 and the wall plane 60b are secured in order that the semiconductor element 23 does not positionally interfere with the wall plane 60a and the wall plane 60b of the concave portion 60. The values of the intervals “p” and “q” are 5 to 10 μm, respectively. A thickness of the layer of the adhesive agent 24 is 5 to 10 μm.

A height of the semiconductor element 23 is, for example, 180 μm.

As the adhesive agent 24, an adhesive material film such as a DAF (Die Attach Film), a thermoplastic resin, and the like may be employed. In the case that the DAF is employed, the provisionally adhered semiconductor element 23 may be moved along a direction of a plane of the bottom plane 60c of the concave portion 60 by elasticity of an adhesive layer contained in the DAF. In the case that a thermoplastic adhesive material is employed, the semiconductor element 23 may be moved by heating the thermoplastic adhesive material so as to soften the adhesive material.

### (S103: Semiconductor Element Aligning Step)

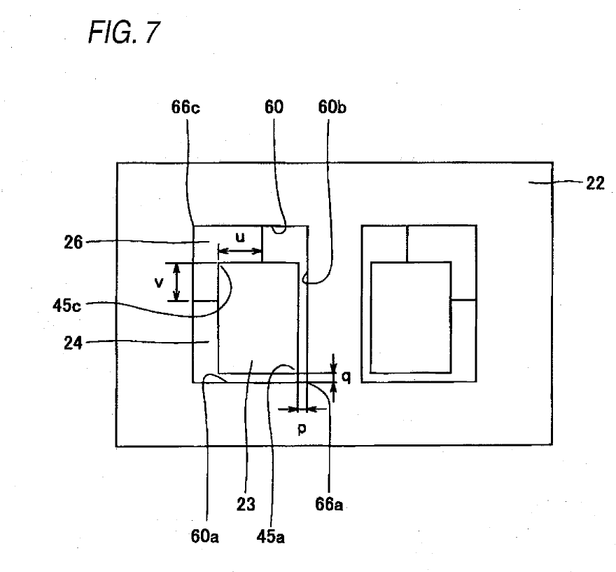

FIG. 7 indicates a situation condition under which a semiconductor element depressing member having a thermal expansion property is provided in the vicinity of a second corner portion 66c of the concave portion 60 in the semiconductor element aligning step.

A semiconductor element depressing member 26 is formed by supplying a material having fluidity to a portion of the concave portion 60 in the vicinity of a second corner portion 66c thereof located opposite to the first corner portion 66a by a potting method, or the like. This semiconductor element depressing member 26 is provided in such a manner that the semiconductor element depressing member 26 is contacted to the second corner portion 66c of the concave portion 60 and is further contacted to a second corner 45c of the semiconductor element 23. Lengths “u” and “v” of portions of the semiconductor element depressing member 26 are approximately 100 μm, which are contacted to the second corner 45c of the semiconductor element 23.

The semiconductor element depressing member 26 has such a property that if the material having the fluidity is solidified and heated after the material has been supplied, then the heated material causes the semiconductor element 23 to be moved due to thermal expansion force. A coefficient of thermal expansion of the semiconductor element depressing member 26 is desirably selected to be higher than, or equal to 300×10⁻⁶/° C. As the material, either a silicone resin or copper paste may be employed.

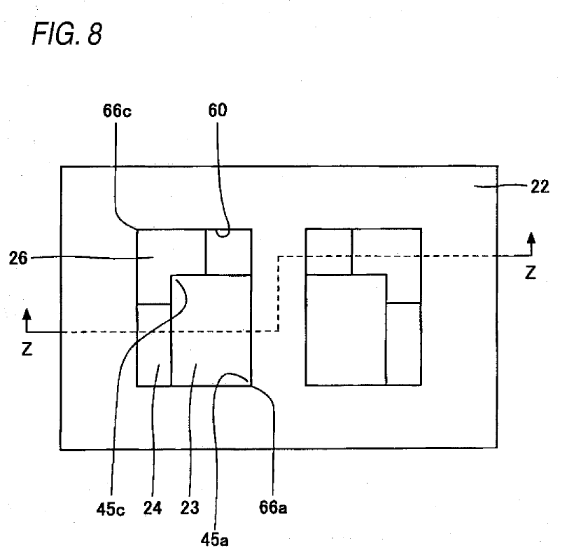

FIG. 8 indicates a setting condition under which the semiconductor element 23 is aligned.

The semiconductor element depressing member 26 depresses the semiconductor element 23 based upon the thermal expansion force and causes the first corner 45a of the semiconductor element 23 to abut against the first corner portion 66a of the concave portion 60 so as to align the semiconductor element 23. As heat capable of thermally expanding the semiconductor element depressing member 26, heat generated from a preheating operation (for instance, 170° C.) performed prior to resin molding may be utilized. The thermal expansion force of the semiconductor element depressing member 26 is influenced to both the second corner portion 66c of the concave portion 60 and the second corner 45c of the semiconductor element 23, to which the semiconductor element depressing member 26 is being contacted. The second corner portion 66c of the concave portion 60 may be regarded as rigidity, whereas the provisionally adhered semiconductor element 23 functioning as the other member may be moved due to the elasticity of the adhesive layer provided on the DAF, or due to softening of the preheated thermoplastic adhesive material. Although the semiconductor element 23 has been arranged with keeping the distances defined by the intervals “q” and “p” between the wall planes 60a and 60b of the concave portion 60 before the semiconductor element 23 is moved (refer to FIG. 7), the semiconductor element 23 is moved toward the first corner portion 66a of the concave portion 60 based upon the depression force exerted by the thermal expansion of the semiconductor element depressing member 26.

The semiconductor element 23 is aligned by that the first corner 45a thereof abuts against the first corner portion 66a of the concave portion 60.

Normally, a preheating operation designates that a member for forming a space into which a molded resin is injected is previously heated to a temperature (for example, 170° C.) of the molded resin to be injected, prior to an injection of the molded resin. As to the thermal expansion of the semiconductor element depressing member 26, the above-described preheating operation can be utilized. Alternatively, other heat sources may be utilized.

### (S104: Resin Molding Step)

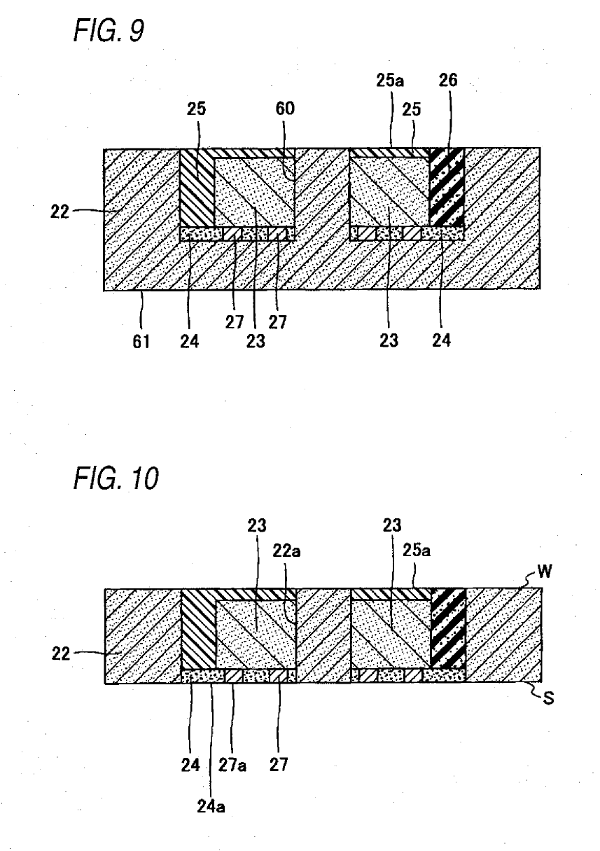

FIG. 9 shows a sectional view of a plate-shaped member, taken along a cutting line “Z-Z” of FIG. 8, to which the resin molding step has been accomplished.

In the Resin Molding Step, the Plate-Shaped Member 22 to which the semiconductor element aligning step (S103) has been accomplished is stored in a molding die of a transfer mold apparatus (not shown), and resin sealing (resin molding) is carried out.

A molded resin 25 is injected from a gate (not shown) of the molding die, and then is filled into a space of the concave portion 60 so as to seal and fix the semiconductor element 23 and the semiconductor element depressing member 26, which are being stored in the concave portion 60.

As the molded resin 25, an epoxy resin, a phenol resin, and the like may be employed.

As a means for sealing the space of the concave portion 60, not only the transfer molding method, but also the potting method may be employed.

### (S105: Electrode Pad Exposing Step)

Next, a plane 61 of the plate-shaped member 22 shown in FIG. 9 on the side of the bottom portion of the concave portion 60 is ground and polished by employing a grinding machine, a polishing machine, and the like. Since the concave portion 60 is opened, a penetration portion 22a is formed and electrode pads 27 are exposed from the plate-shaped member 22.

FIG. 10 shows a situation condition under which the electrode pads 27 of the semiconductor element 23 are under exposed conditions.

Due to the grinding and polishing treatments, a surface 27a of the electrode pads 27 exposed from the plate-shaped member 22, a plane of the plate-shaped member 22, and a surface 24a of the layer of the adhesive agent 24 are brought into an in-plane condition, so that a first plane “S” is formed.

### (S106: Wiring Board Stacking Step)

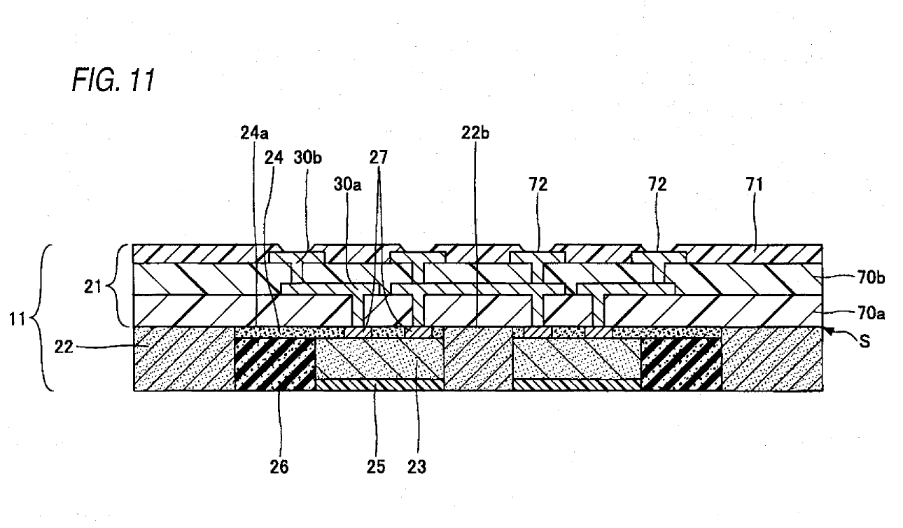

FIG. 11 indicates a situation condition under which in the wiring board stacking step, the electrode pads 27 are connected to a wiring layer 30a of a wiring board 21, and the wiring board 21 is stacked on the first plane “S” of the plate-shaped member 22.

The wiring board 21 is formed by that edge planes of vias of the wiring layers 30a are directly connected to the electrode pads 27, and while both the plate-shaped member 22 and the semiconductor element 23 are provided as a base body, insulating layers and wiring layers are formed by being stacked on each other in a film form.

While the wiring board 21 constitutes either a wiring board made of a single layer or a wiring board made of multiple layers, stacked layers of the wiring board 21 may be formed by employing a semiconductor manufacturing process which is well known in the technical field. That is, in FIG. 11, a first layer constructed of both an insulating layer 70a and the wiring layer 30a is stacked on the first plane “S” of the plate-shaped member 22 by employing a photolithography method. Subsequently, if required, a second layer constructed of an insulating layer 70b and a wiring layer 30b may be stacked on the first layer, and then, insulating layers and wiring layers may be repeatedly stacked on the second layer, so that a multi-layer wiring board may be formed.

As to a thickness of the wiring board 21, for instance, a thickness of a single layer of the insulating layers 70a and 70b is 5 to 30 μm. Also, a thickness of a solder resist layer 71 is 20 to 30 μm. A thickness of the wiring board 21 when the wiring board 21 has two layers of insulating layers is, for instance, 30 to 100 μm.

As a material of the plate-shaped member 22, silicon, glass, or the like may be employed; and a thickness thereof is, for instance, 200 to 300 μm. While the plate-shaped member 22 may be employed as a base body on which the above-described multilayer wiring board may be stacked, the plate-shaped member 22 has such a strength capable of holding an entire portion of a semiconductor device 11.

Although the thickness of the wiring board 21 has been schematically illustrated to be nearly equal to the thickness of the plate-shaped member 22 in FIG. 11, in embodied dimensions, a thickness of a plate-shaped member is thicker than a thickness of a wiring board stacked on the plate-shaped member.

While an epoxy resin and the like are employed as the material of the insulating layers 70a, 70b, . . . , a multilayer wiring board may be formed by a build-up method. For instance, the multilayer wiring board may be formed by executing the below-mentioned respective steps, namely, insulating layers are formed by employing an epoxy resin; the formed insulating layers are exposed, developed, and etched so as to form interlayer vias; a seed layer is formed; copper is electrolytically plated and etched so as to form wiring layers; the insulating layers and the wiring layers are repeatedly stacked on each other; a solder resist layer is formed; and an external connecting means such as solder balls are formed.

Also, in order to form an interlayer via which electrically connects wiring layers to each other, a laser treatment may be employed.

In addition, while silicon, glass, and the like are employed as the material of the insulating layers 70a, 70b, . . . , a multilayer wiring board may be formed by employing a well-known photolithography method of a semiconductor manufacturing process.

In accordance with this step, a wiring board of very fine wiring lines can be formed. As numeral values of the very fine wiring lines, for example, an L/S (Line/Space, i.e., widths of wiring lines and intervals thereof) may be selected to be 1/1 μm to 5/5 μm.

The semiconductor device 11 featured by the high alignment precision of the semiconductor element 23 can be manufactured by performing the above-described steps.

It should be understood that as concrete examples of the semiconductor elements 23 and 23, CPUs (Central processing Units) may be employed with each other, a CPU may be employed with a memory, a CPU may be employed with a GPU (Graphical Processing Unit), and the like.

### Advantage of First Embodiment Mode

In accordance with the first embodiment mode of the present invention, since the semiconductor element is caused to abut against the wall planes of the concave portion of the plate-shaped member, the positions of the semiconductor element can be set in high precision by utilizing the solid wall planes. As a result, the alignment problem caused by the solder does not occur, which may appear in the conventional flip chip joining. In other words, there is no deviation in the positional setting, which is caused by the surface tension of the melted solder, but also, securing of the distances for separating the solder bumps from each other is no longer required. As a consequence, the higher alignment precision of the semiconductor element can be achieved, so that the wiring board having the very fine wiring lines can be formed. Since the high alignment precision can be realized by utilizing the solid wall planes, such very fine wiring lines can be realized that the L/S in the wiring board is defined of the order of 1/1 μm to 5/5 μm.

Also, since the wiring board can be directly connected to the semiconductor element and the plate-shaped member, these elements are no longer required to be connected to each other by employing solder. As a consequence, a shortcircuit does not occur which is caused by migrations of solder metals, so that the semiconductor device having the high quality can be manufactured in the high reliability.

Also, since the silicon material having the rigidity and the like can be used as the material of the plate-shaped member, the semiconductor device with a small number of cambers can be provided.

Furthermore, since the plate-shaped member can be grinded so as to change the thickness thereof into the predetermined thickness, the slim type semiconductor device can be provided.

### Modification 1 of First Embodiment Mode

A modification 1 of the first embodiment mode of the present invention is an example of a manufacturing method related to forming of a concave portion of a plate-shaped member in the concave portion forming step.

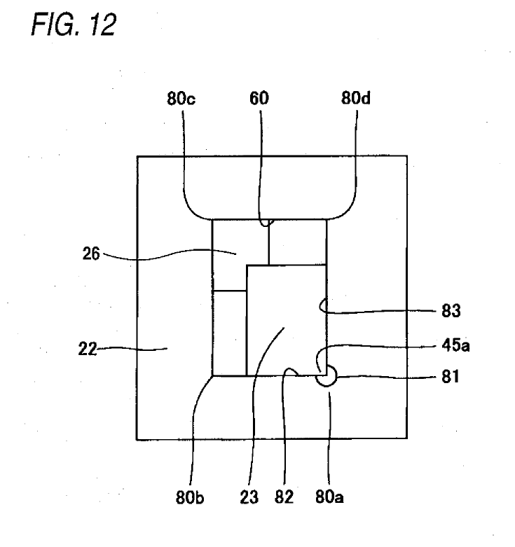

FIG. 12 shows such a plate-shaped member 22 that a shape of a corner portion in the first corner portion 80a of the concave portion 60 is a notch 81 having a partial circle in the concave portion forming step (S101). FIG. 12 indicates a position of the semiconductor element 23 in addition to the above-described elements. Since the notch 81 having the partial circle is provided at the corner in the first corner portion 80a, a peak portion of the first corner 45a of the semiconductor element 23, which is located opposite to the first corner portion 80a, is not contacted to the first corner portion 80a even when a shape of the first corner portion 80a is different from the shape of the corner portion in such a case that the notch 81 is not formed. As a result, there is no deviation in the alignments of the semiconductor elements 23 due to the difference of the shapes. As a consequence, two edges which constitute the first corner 45a of the semiconductor element 23 abut against two edges 82 and 83 of the concave portion 60, and thus, the two edges thereof are precisely aligned, so that higher alignment precision of the semiconductor element 23 can be secured.

Then, the shape of the notch 81 is not limited only to the partial circle, but also, an elongate hole and other arbitrary figures may be alternatively selected.

In addition to a method for notching a corner portion of the concave portion 60 of the plate-shaped member 22, in such a case that the semiconductor element 23 can be chamfered, the first angle 45a of the semiconductor element 23 can be chamfered, so that high alignment precision of the semiconductor element 23 can be secured, while a peak portion of the chamfered first angle 45a is not fitted to the first angle portion 80a of the concave portion 60.

It should be noted that in the present invention, as to “corner portion”, as shown in FIG. 12, the modification about the shape of the corner portion of the plate-shaped member 22 may also be covered by a technical idea “semiconductor element is caused to abut against two wall planes which constitute first angle portion.”

### Modification 2 of First Embodiment Mode

A modification 2 of the first embodiment mode of the present invention is an example as to a shape of a corner portion of a concave portion which is contacted to the semiconductor element depressing member 26.

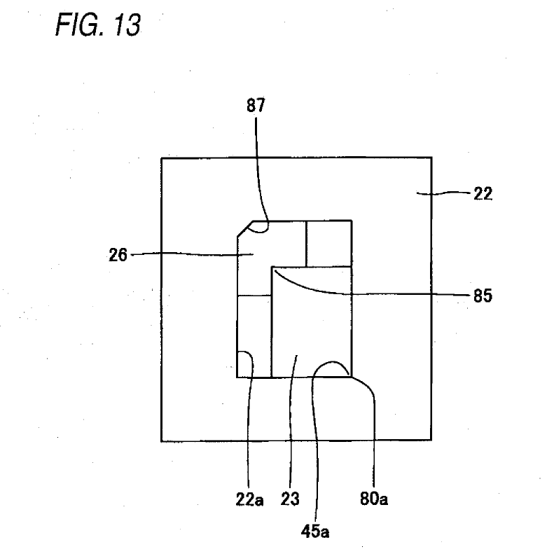

FIG. 13 shows a situation condition under which a chamfer 87 is provided at the second corner portion 80c of the concave portion 60, which is located opposite to the first corner portion 80a thereof and is contacted to the semiconductor element depressing member 26 in the semiconductor element aligning step (S103). Since the chamfer 87 is provided, the semiconductor element depressing member 26 can firmly and effectively perform an alignment operation capable of depressing and moving the semiconductor element 23 along a direction of the first corner portion 80a.

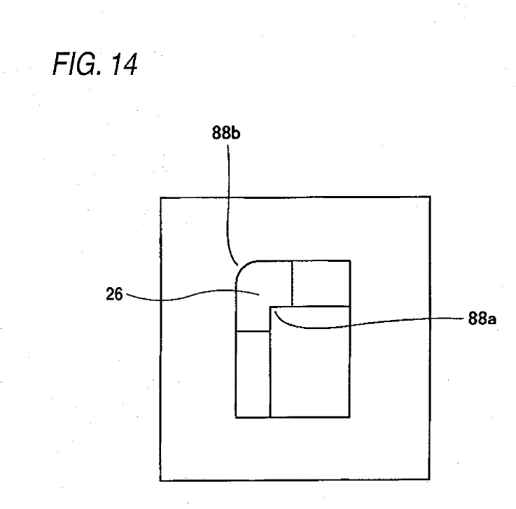

FIG. 14 is an example of forming of another chamfer 88b having a partial circular shape, instead of the chamfer 87 in FIG. 13. Alternatively, the partial circular shape may be replaced by a shape of a smooth curve. Moreover, in order to increase a contact length with respect to the semiconductor element depressing member 26, the portion of the chamfer 88b may be alternatively replaced by a corrugated portion.

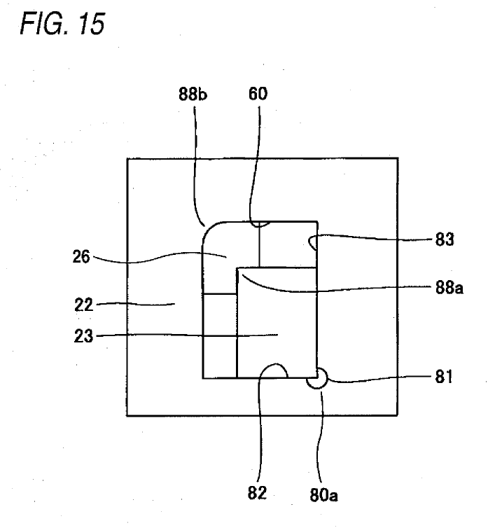

FIG. 15 is an example as to forming of corner portions of the concave portion 60 by combining the notch 81 shown in FIG. 12 with the chamfer 88b shown in FIG. 14. In addition to the above-described example, various sorts of modes that semiconductor elements abut against corner portions may be formed by properly combining shapes of the corner portions with chamfers of the semiconductor elements, so that the semiconductor elements may be effectively aligned.

### Modification 3 of First Embodiment Mode

A modification 3 of the first embodiment mode of the present invention is an example of such a case that a shape of a semiconductor element and a shape of an opening of a concave portion are squares.

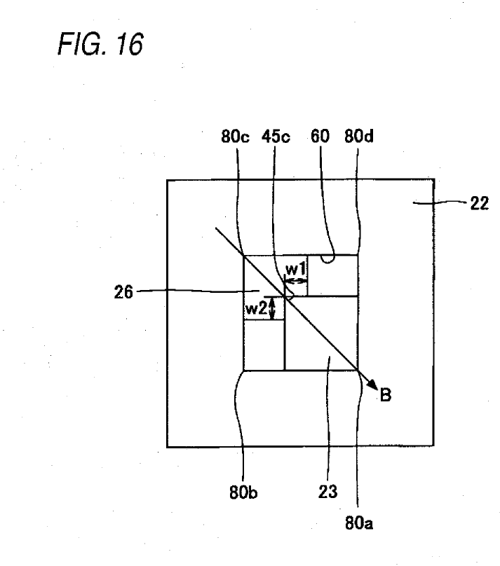

FIG. 16 shows an arranging condition of the semiconductor element depressing member 26 in such a case that the shape of the semiconductor element 23 and the shape of the opening of the concave portion 60 are squares.

With respect to the semiconductor element depressing member 26 provided in the vicinity of the second corner portion 80c of the concave portion 60, a length “w1” and another length “w2” of the semiconductor element depressing member 26 may be made substantially equal to each other, which are contacted to two edges of the semiconductor element 23 located near the second corner 45c thereof. When the semiconductor element depressing member 26 depresses the semiconductor element 23 based upon thermal expansion force thereof so as to cause the semiconductor element 23 to abut against wall planes of the concave portion 60, the semiconductor element depressing member 26 can effectively depress the semiconductor element 23 without an occurrence of any positional deviation along a direction of an arrow “B”, along which a diagonal of the concave portion 60 is made coincident with a diagonal of the semiconductor element 23.

Also, with respect to the shapes of the corner portions 80a, 80b, 80c, 80d of the concave portions 60 shown in FIG. 12 to FIG. 15, these shapes may be simultaneously utilized in order to more effectively align the semiconductor elements 23.

### Modification 4 of First Embodiment Mode

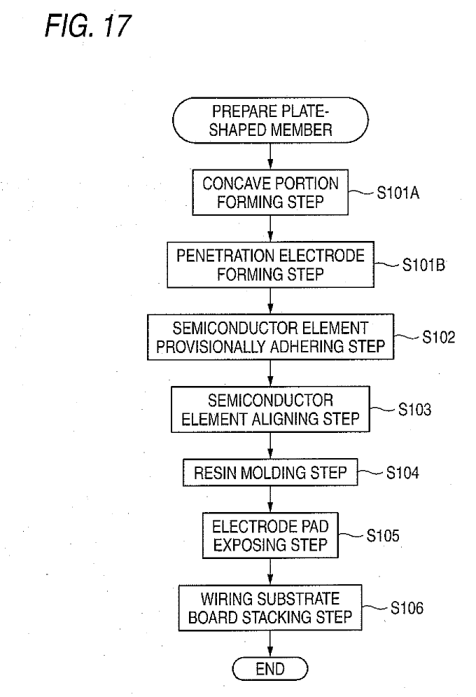

FIG. 17 is a flow chart for indicting steps of a manufacturing method for a semiconductor device, by which penetration electrodes are provided in a plate-shaped member. In comparison with the steps of FIG. 2, steps (S101A) and (S101B) are different from these steps of FIG. 2.

In a concave portion forming step (S101A), either at the same time when the concave portions 60 are formed or just after the concave portions 60 have been formed, for instance, penetration electrode-purpose holes having diameters of approximately 100 μm are pierced. The holes are pierced by, for example, a dry etching process, and also, may be pierced by a laser process. Moreover, in a penetration electrode forming step (S101B), penetration electrodes 29 are formed based upon well-known methods such as a seed layer forming method, a masking method, an electrolytic plating method, and an etching method.

As materials of the penetration electrodes 29, for instance, Cu, Ni, Au, and the like may be employed.

FIG. 18 represents a situation condition under which the penetration electrodes 29 are provided in peripheral areas of opening portions of the concave portions 60 in the plate-shaped member 22.

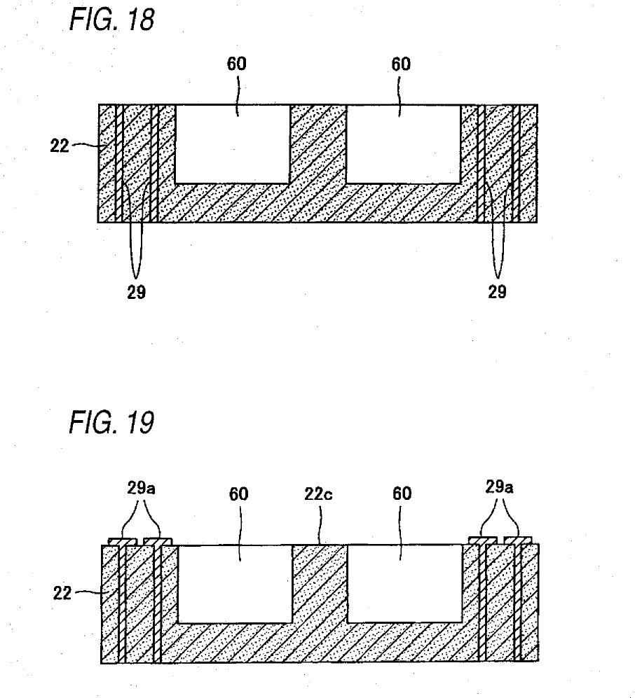

FIG. 19 is a diagram for showing such a case that in the plate-shaped member 22, connection pads 29a are present on edge planes of the penetration electrodes 29 on the side of an opening plane 22c of the concave portions 60. The penetration electrodes 29 having the connection pads 29a may also be formed in accordance with the above-described step (S101B).

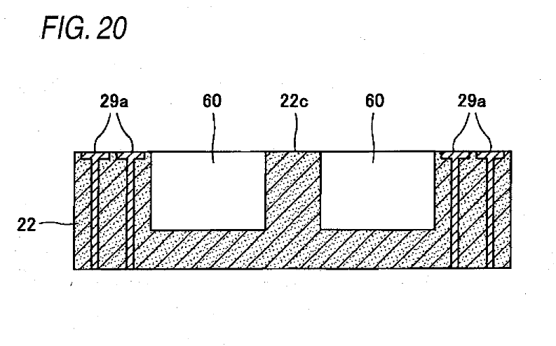

FIG. 20 is such an example that while a portion of the connection pads 29a of the penetration electrodes 29 is located within the plate-shaped member 22, surfaces of the connection pads 29a and the opening plane 22c of the concave portions 60 in the plate-shaped member 22 are brought into an in-plane condition.

### Modification 5 of First Embodiment Mode

A modification 5 of the first embodiment mode is an example of a manufacturing method for a semiconductor device, which is featured by that a molded resin on a plate-shaped member is ground and polished.

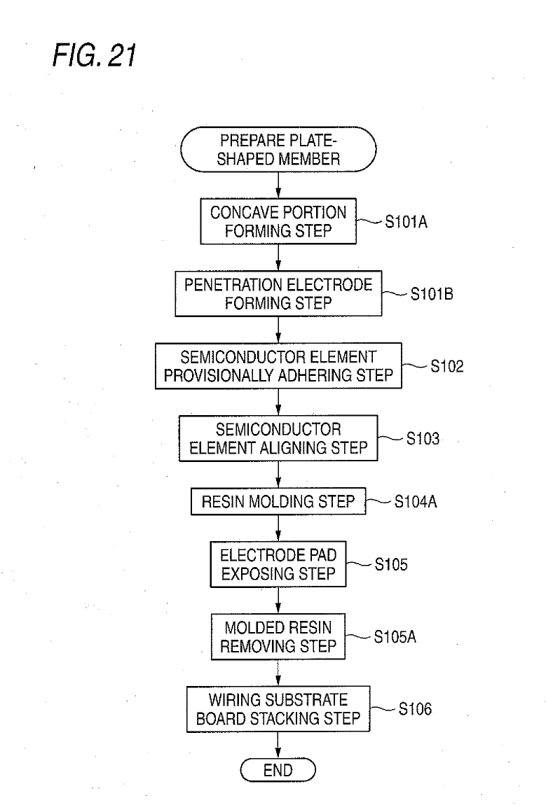

FIG. 21 is a flow chart for showing steps of a manufacturing method for a semiconductor device, according to the modification 5 of the first embodiment mode. In comparison with the steps of FIG. 17, both a resin molding step (S104A) and a molded resin removing step (S105A) are different in the steps of FIG. 21.

In the resin molding step (S104A), both the semiconductor element 23 and the semiconductor element depressing member 26 stored in the concave portion 60 are sealed by employing a resin. Further, a resin is molded on a plane of the plate-shaped member 22, which is located opposite to the side of the electrode pads 27 of the semiconductor element 23 so as to provide a molded resin 25.

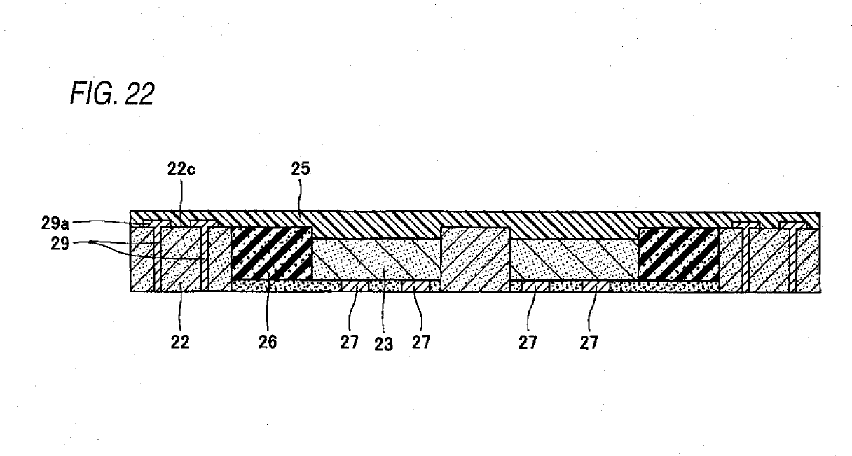

Next, as shown in FIG. 22, the electrode pads 27 are exposed (S105: electrode pad exposing step), and in the subsequent molded resin removing step (S105A), the molded resin 25 is grinded and polished.

In the molded resin removing step (S105A), in such a case that connection pads 29a projected from the plane 22c of the plate-shaped member 22 are present, as indicated as the mode of the connection pads 29a in FIG. 22, since the layer of the molded resin 25 is grinded and polished, the connection pads 29a can be exposed from the layer of the molded resin 25.

### Second Embodiment Mode

A second embodiment mode of the present invention is an example of a semiconductor device 11 featured by employing a semiconductor element fixed on a plate-shaped member in high alignment precision, and a wiring board directly stacked on the semiconductor element.

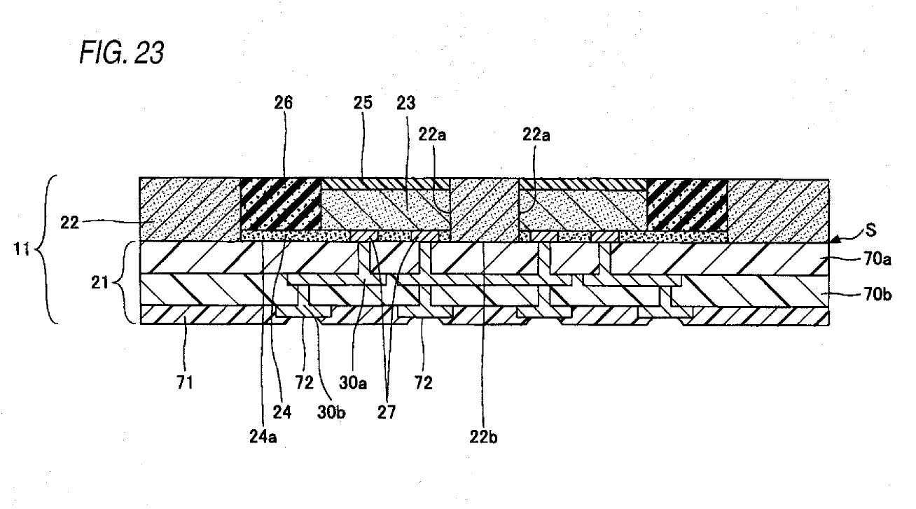

In FIG. 23, the semiconductor device 11 is provided with a plate-shaped member 22, a molded resin 25, and a wiring board 21.

The plate-shaped member 22 has a semiconductor element 23 and a semiconductor element depressing member 26 in a penetration portion 22a.

As a material of the plate-shaped member 22, silicon, glass, or the like may be employed, and a thickness thereof is, for instance, 200 to 300 μm.

A coefficient of thermal expansion of the semiconductor element depressing member 26 is desirably selected to be higher than, or equal to 300×10⁻⁶/° C. As a material of the semiconductor element depressing member 26, either a solidified silicone resin or solidified copper paste may be employed.

The molded resin 25 seals both the semiconductor element 23 and the semiconductor element depressing member 26 stored in the penetration portion 22a so as to fix these elements 23 and 26.

The wiring board 21 is formed as follows: That is, the wiring board 21 is directly connected to the plate-shaped member 22; wiring layers 30a and 30b are alternately stacked on insulating layers 70a and 70b; the wiring layers 30a and 30b are electrically connected to each other; vias of the wiring layer 30a are directly connected to electrode pads 27 of the semiconductor element 23; and the wiring board 21 is directly stacked on a first plane “S” of the plate-shaped member 22. It should be noted that the wiring board 21 may be made of a single layer, or multiple layers.

As the wiring board 21, a high density wiring-purpose substrate board such as a resin substrate board using an epoxy resin and the like, and a substrate board using either silicon or glass, may be employed.

A height of the semiconductor element 23 is, for instance, 180 μm.

It should be understood that as concrete examples of the semiconductor elements 23 and 23, CPUs (Central processing Units) may be employed with each other, a CPU may be employed with a memory, a CPU may be employed with a GPU (Graphical Processing Unit), and the like.

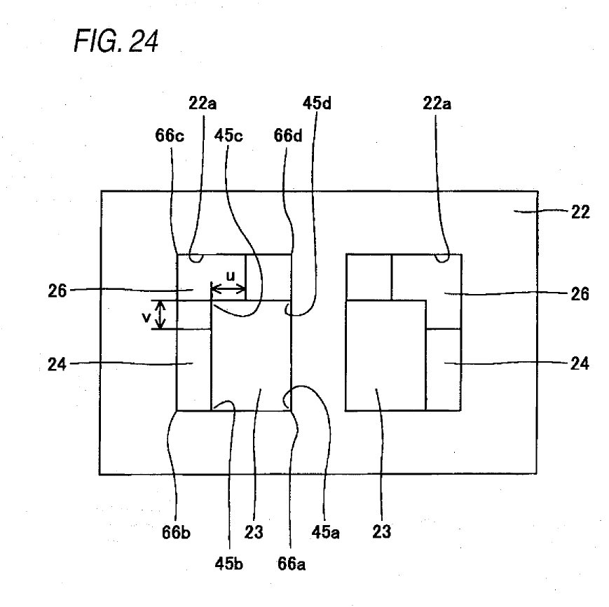

FIG. 24 is a plan view of the semiconductor device 11, as viewed from the opposite side of the electrode pads 27 of the semiconductor element 23 (being illustrated after molded resin has been removed). The plate-shaped member 22 in FIG. 24 has the penetration portions 22a, while the penetration portions 22a store thereinto the semiconductor elements 23 and the semiconductor element depressing members 26.

The semiconductor element depressing member 26 is provided at a second corner portion 66c located opposite to a first corner portion 66a of the penetration portion 22a. Lengths “u” and “v” of portions of the semiconductor element depressing member 26 are approximately 100 μm, which is contacted to the second corner 45c of the semiconductor element 23.

The semiconductor element 23 is aligned by that a first corner 45a of the semiconductor element 23 abuts against the first corner portion 66a possessed by the penetration portion 22a based upon thermal expansion force of the semiconductor element depressing member 26 being contacted to the second corner 45c of the semiconductor element 23.

The high alignment precision of the semiconductor element may be achieved by securing of positional setting precision based upon the abutment of the semiconductor element by utilizing the wall planes of the penetration portion of the plate-shaped member, namely, by utilizing the solid wall planes thereof.

As to a heat amount capable of thermally expanding the semiconductor element depressing member 26, this heat amount may be obtained by utilizing, for example, a heat amount of a preheating operation performed prior to resin molding of the semiconductor element 23, and the like. However, the generation of this heat amount is not limited only to the preheating operation, but also other heat sources may be utilized.

As numeral values of very fine wiring lines of the wiring board 21, for example, an L/S (Line/Space, i.e., widths of wiring lines and intervals thereof) may be selected to be 1/1 μm to 5/5 μm.

### Advantage of Second Embodiment Mode

In accordance with the second embodiment mode of the present invention, since the semiconductor element is caused to abut against the wall planes of the penetration portion of the plate-shaped member, the positions of the semiconductor element can be set in high precision by utilizing the solid wall planes thereof. As a result, the wiring board having the very fine wiring lines can be formed.

Also, since the wiring board can be directly connected to the plate-shaped member without employment of solder, a shortcircuit does not occur which is caused by migrations of solder metals, so that the semiconductor device having the high quality can be manufactured in the high reliability.

### Modification of Second Embodiment Mode

A modification of the second embodiment mode of the present invention is an example of a semiconductor device featured by that penetration electrodes are provided in a circumferential area of penetration portions of a plate-shaped member.

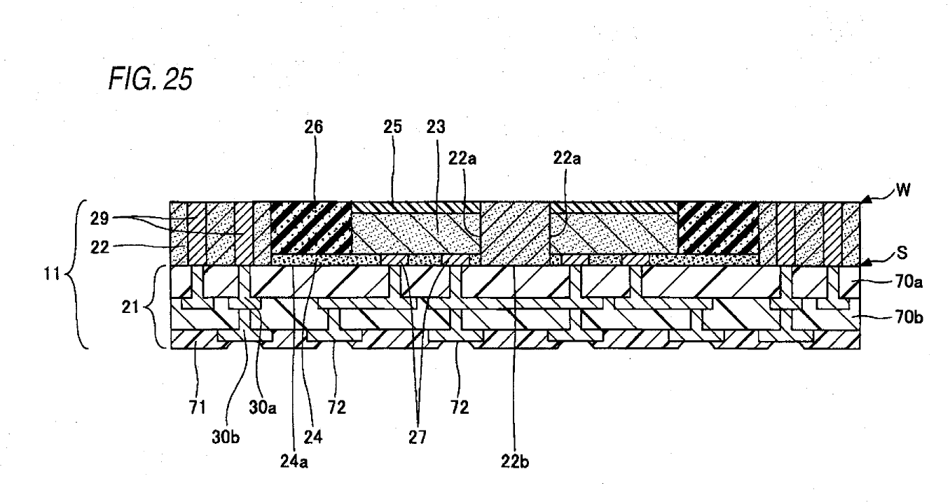

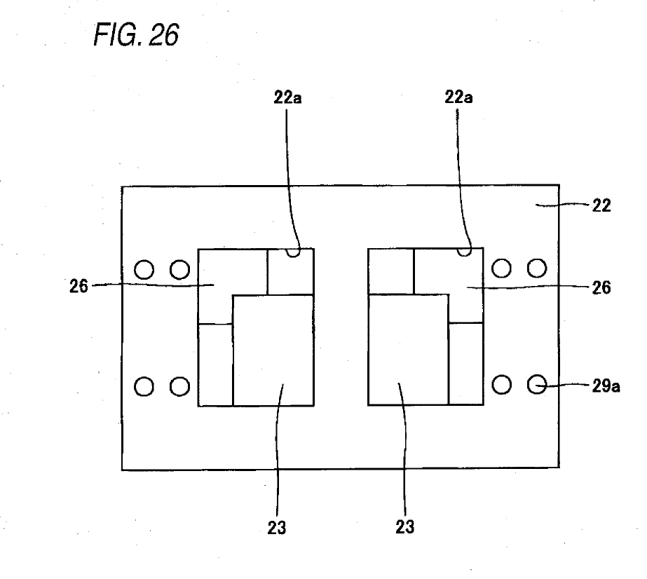

FIG. 25 is a sectional view for showing a semiconductor device 11 in which a wiring board 21 is stacked on a plate-shaped member 22 having penetration electrodes 29 at a circumferential area of penetration portions 22a. FIG. 26 is a plan view (being illustrated after molded resin has been removed) of the semiconductor device 11, as viewed from a second plane “W” which is located opposite to the first plane “S” of the plate-shaped member 22.

The semiconductor device 11 according to the modification of the second embodiment mode has such a different structure that penetration electrodes 29 are provided, as compared with the above-described semiconductor device 11 (FIG. 23) of the second embodiment mode.

As materials of the penetration electrodes 29, for instance, Cu, Ni, Au, and the like may be employed.

The semiconductor device 11 mounts other semiconductor devices (not shown) on the side of the second plane “W” of the plate-shaped member 22 by being electrically connected to the penetration electrodes 29, so that an electronic device can be formed as the entire structure. When other semiconductor devices are mounted, for instance, the connection pads 29a shown in FIG. 19, FIG. 20, and the like are formed on edge portions of the penetration electrodes 29 on the side of the second plane “W”, and thus, mounting of other semiconductor devices may be carried out via internal connection terminals. Also, a newly provided wiring board may be electrically connected to the penetration electrodes 29, and furthermore, may be directly stacked on the edge planes of the penetration electrodes 29 on the side of the second plane “W.” The above-described newly provided wiring board may be provided with other semiconductor elements, other electronic components, and the like.

### Third Embodiment Mode

A third embodiment mode of the present invention is an example of an electronic device 10 in which a semiconductor device (refer to second embodiment mode) having a semiconductor element fixed on a plate-shaped member in high alignment precision is connected to another semiconductor device via an internal connection terminal.

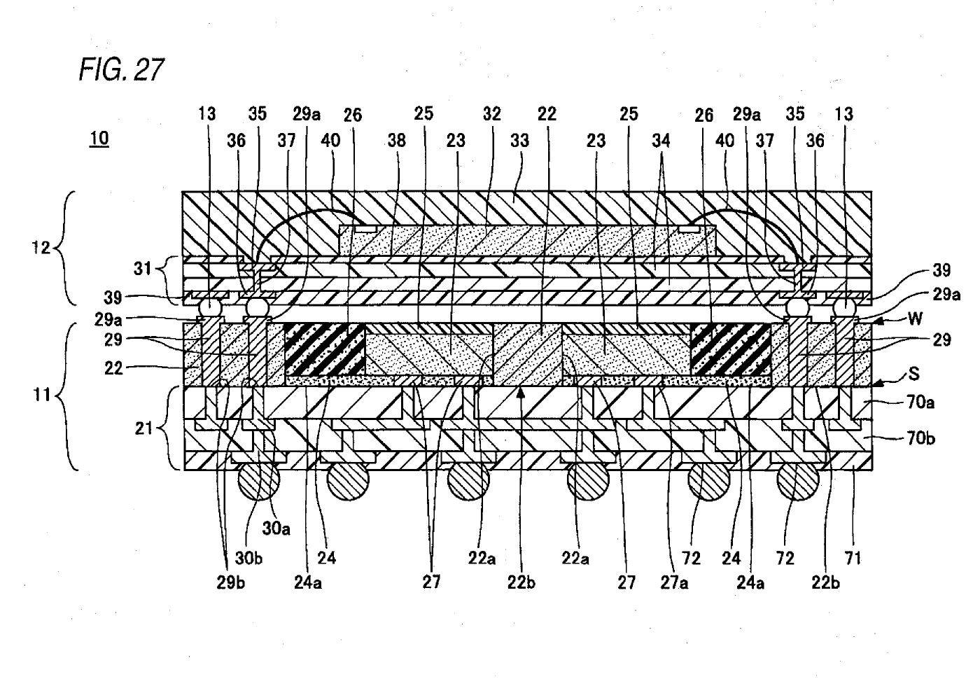

FIG. 27 indicates the electronic device 10 in which connection pads 29a of penetration electrodes 29 of a semiconductor device 11 and pads 36 of a semiconductor device 12 are connected to internal connection terminals 13 such as solder balls so as to connect the semiconductor device 11 to the above-described another semiconductor device 12.

Alternatively, the internal connection terminals 13 may be provided in any one of the semiconductor device 11 and another semiconductor device 12.

As the semiconductor device 11, the semiconductor device (namely, modification of second embodiment mode) having the penetration electrodes 29 may be used.

The above-described another semiconductor device 12 is provided with, for example, a wiring board 31, a semiconductor element 32, and a molded resin 33.

The semiconductor element 32 is connected to pads 35 provided on the wiring board 31 by metal wires 40. The pads 35 are electrically conducted to the semiconductor device connection-purpose pads 36, so that the semiconductor device 11 is electrically connected to the semiconductor device 12.

As the semiconductor element 32, for example, a memory element may be employed.

As the wiring board 31, for instance, a multiple stacked layer substrate may be employed.

It should be understood that the above-explained another semiconductor device 12 may be manufactured in a similar mode to that of the semiconductor device 11. Further, the semiconductor device 12 may be alternatively realized as a semiconductor element, or an electronic component other than a semiconductor element.

Also, in FIG. 27, although the internal connection terminals 13 such as the solder balls have been illustrated in order to connect the semiconductor device 11 to the above-described another semiconductor device 12, another structure may be alternatively made. That is, while the semiconductor device 11 and this semiconductor device 12 may be directly connected to the penetration electrodes 29, the multiple stacked layer substrate may be directly stacked also on the side of the second plane “W” of the plate-shaped member 22.

### Advantage of Third Embodiment Mode

In accordance with the third embodiment mode of the present invention, since the semiconductor device indicated in the above-explained second embodiment mode is used to be connected to another semiconductor device, the compact and high-density electronic device having the high reliability can be provided.

Since the above-described semiconductor device of the second embodiment mode is such a semiconductor device having a wiring board capable of achieving very fine wiring lines by employing a semiconductor element whose high alignment precision is maintained, an electronic device manufactured in high density can be provided by connecting the above-explained semiconductor device to another semiconductor device.

Also, as to the semiconductor device of the second embodiment mode, which is utilized when the electronic device of the third embodiment mode is manufactured, the higher reliability can be obtained by connecting the wiring board to the plate-shaped member without employment of the soldering connection. As a result, since the above-described semiconductor device of the second embodiment mode is connected to another semiconductor device having high reliability, such an electronic device having high reliability can be provided.

Although the preferred embodiment modes of the present invention have been described in detail, the present invention is not limited only to the above-explained embodiment modes, but various sorts of modifications and substitutions may be applied to the above-described embodiment modes without departing from the technical scope of the present invention.

What is claimed is:

1. A method for manufacturing a semiconductor device having a plate-shaped member which stores thereinto a semiconductor element,
the manufacturing method comprising:
a concave portion forming step for forming a concave portion in the plate-shaped member, an opening portion of the concave portion being a rectangle and the concave portion being used to store thereinto the semiconductor element;
a semiconductor element provisionally adhering step for provisionally adhering the semiconductor element to an adhesive layer in such a manner that the adhesive layer is formed on a bottom of the concave portion, the semiconductor element is mounted on a portion of the concave portion in the vicinity of a first corner portion thereof, and at least a portion of an electrode pad of the semiconductor element is embedded in the adhesive layer; and
a semiconductor element aligning step for aligning the semiconductor element in such a manner that a semiconductor element depressing member for aligning the semiconductor element is formed at a second corner portion located opposite to the first corner portion of the concave portion, and the semiconductor element depressing member causes the semiconductor element to abut against two wall planes which constitute the first corner portion based upon expansion of the semiconductor element depressing member due to heating operation.

2. The manufacturing method of a semiconductor element as in claim 1, wherein
a thermal expansion coefficient of the semiconductor element depressing member is higher than or equal to 300×10⁻⁶/° C.

3. The manufacturing method of a semiconductor element as in claim 1, wherein
the concave portion forming step includes a penetration electrode forming step for forming a penetration electrode at a circumferential area of the opening portion of the concave portion in the plate-shaped member.

4. The manufacturing method of a semiconductor element as in claim 1, further comprising:
a resin sealing step for sealing the concave portion by a resin, in which the semiconductor element and the semiconductor element depressing member are stored;
an electrode pad exposing step for exposing the electrode pad from the plate-shaped member; and
a wiring board stacking step for stacking a wiring board having an insulating layer and a wiring layer electrically connected to the electrode pad on the plate-shaped member in the form of a single layer or multiple layers.

5. The manufacturing method of a semiconductor element as in claim 1, further comprising:
a sealing resin removing step for forming a resin layer made by a sealing resin on a plane of the semiconductor element on the side opposite to the side of the electrode pad, and a plane of the plate-shaped member on the same side as the opposite side of the semiconductor element, and for removing a portion of the resin layer;
an electrode pad exposing step for exposing the electrode pad from the plate-shaped member; and
a wiring board stacking step for stacking a wiring board having an insulating layer and a wiring layer electrically connected to the electrode pad on the plate-shaped member in the form of a single layer or multiple layers.

6. A semiconductor device comprising:
a plate-shaped member for storing thereinto a semiconductor element, wherein
the plate-shaped member has a penetration portion having a rectangular opening shape, in which the semiconductor element and a semiconductor element depressing member for aligning the semiconductor element are provided;
the semiconductor element depressing member is provided at a second corner portion of the penetration portion, which is located opposite to a first corner portion thereof;
the semiconductor element is aligned in such a manner that the semiconductor element abuts against two wall portions which constitute the first corner portion based upon thermal expansion of the semiconductor element depressing member; and
the semiconductor element and the semiconductor element depressing member provided in the penetration portion are sealed by a sealing resin.

7. The semiconductor device as in claim 6, wherein
a thermal expansion coefficient of the semiconductor element depressing member is higher than or equal to 300×10⁻⁶/° C.

8. The semiconductor device as in claim 6, wherein
a wiring board having a wiring layer which is connected to an electrode pad provided in the semiconductor element is stacked in a single layer form or a multilayer form.

9. The semiconductor device as in claim 6, wherein
a penetration electrode is provided at a circumferential area of the penetration portion.

10. The semiconductor device as in claim 6, wherein
a corner portion at the first corner portion of the penetration portion has a notch shape.

11. An electronic device comprising:
the semiconductor device as in claim 6;
another semiconductor device; and
an internal connection terminal which is arranged between the semiconductor device and the another semiconductor device and electrically connects the semiconductor device to the another semiconductor device.
